(19) United States
(12) Patent Application Publication
(10) Pub. No.: US 2011/0265866 A1
(43) Pub. Date: Nov. 3, 2011

(54) SOLAR CELL AND METHOD FOR MANUFACTURING THE SAME

(76) Inventors: Min-Seok Oh, Yongin-si (KR); Jung-Ho Song, Yongin-si (KR); Yoon-Mook Kang, Suwon-si (KR); Nam-Kyu Song, Hwaseong-si (KR); Min Park, Seoul (KR); Jung-Tae Kim, Seoul (KR); Yun-Seok Lee, Seoul (KR); Cho-Young Lee, Suwon-si (KR); Dong-Hwan Kim, Seoul (KR); Joon-Sung Lee, Seoul (KR); Sung-Ju Tark, Seoul (KR)

(21) Appl. No.: 13/004,635

(22) Filed: Jan. 11, 2011

(30) Foreign Application Priority Data
Apr. 28, 2010 (KR) 10-2010-0039424

(51) Int. Cl. H01L 31/06; H01L 31/18

(52) U.S. Cl. 136/255; 438/57; 257/E31.001

(57) ABSTRACT

A solar cell is provided with a hetero-junction front structure (e.g., P/N or P/I/N) and is further provided in a back portion of thereof with a passivation layer having a plurality of openings defined therethrough. A BSF-forming binder material and a back face electrode are provided contacting the back surface and are fired to thereby bind the back face electrode to the structure and to form a BSF region extending from the openings of the passivation layer.

### CROSS-REFERENCE TO RELATED APPLICATION

This application claims priority to and benefit of Korean Patent Application No. 10-2010-0039424 filed in the Korean Intellectual Property Office on Apr. 28, 2010, the entire contents of which application are incorporated herein by reference.

### BACKGROUND

(a) Field of Disclosure

The present disclosure of invention relates to a solar cell and a manufacturing method thereof.

(b) Description of Related Technology

A photovoltaic (PV) style solar cell has a photoelectric conversion element that converts received radiant solar energy into electrical energy. PV solar cells have recently been spotlighted as pollution-free and unlimited next-generation energy providers.

The PV solar cell typically includes a p-type semiconductor and an n-type semiconductor. It may also include an intrinsic layer interposed between the P and N type regions to thereby define a PIN structure. When radiant solar energy is absorbed for example at a junction (p-n junction) of the P and N type regions, an electron-hole pair (EHP) may be generated inside the semiconductor body at the location of absorption. Each of the generated electron and hole may then respectively move into the n-type semiconductor (gathers electrons, e⁻) and the p-type semiconductor (gathers positive charge carriers, holes), and then they may be respectively gathered into respective, ohmicly connected metal or other electrodes such that their energy may be used for performing useful electrical work (electrical energy applications).

On the other hand, it is important for a solar cell to have increased efficiency to output as much electrical energy from solar energy as possible. To increase the efficiency of a solar cell, it is important to generate as many free electron-hole pairs as possible inside the semiconductor, however it is also important to output the generated charges without loss occurring due for example to recombination of the generated free electron-hole pairs.

One of the reasons that solar-generated charges may be lost is extinction wherein the generated electron and hole recombine with each other or with adjacent opposite charges before they migrate to the charge-trapping N or P region and thus the energy of the generated EHPs is lost (e.g., as waste heat).

The above information disclosed in this Background section is only for enhancement of understanding of the background of the invention and therefore it may contain information that does not form the prior art that is already known to persons of ordinary skill in the pertinent art.

### SUMMARY

In accordance with the present disclosure of invention, a front surface structure of a semiconductive bulk substrate has a hetero-junction formed thereat while a passivation layer having a plurality of openings is formed at a back face of the solar cell. An electrode contacting the back surface of the semiconductor substrate through the opening is provided at the back surface of the semiconductor substrate and bound thereto with use of a binding agent or paste such that a solar cell of high efficiency is provided. When the back surface electrode is bound to the front structure, a back surface electric field (BSF) layer portion is formed at region communicating with the opening in the passivation layer and this BSF layer portion operates to reduce the speed of extinction due to recombination of electrons and holes.

A solar cell according to a first exemplary embodiment includes: a first semiconductive substrate; a second semiconductive layer formed on a first surface of the first semiconductive substrate; a first electrode formed on the second semiconductive layer; at least one passivation layer formed on a second surface of the first semiconductive substrate; at least one opening formed in the passivation layer; and a second electrode contacting the second surface of the first semiconductive substrate through the opening.

An amorphous intrinsic silicon thin film is optionally formed between the first surface of the first semiconductive substrate and the second semiconductive layer to thereby form a PIN heterojunction structure.

At least one thin film selected from amorphous silicon carbide (a-SiC), an amorphous silicon oxide (a-SiO), and an amorphous silicon nitride (a-SiN) may be further included between the amorphous silicon thin film and the second semiconductive layer.

A transparent conductive layer may be further formed between the second semiconductive layer and the first electrode.

The transparent conductive layer may include at least one transparent conductive material selected from ITO, a-ITO, IZO, ZnO, and SnOx.

The first electrode may be made of one or more of silver (Ag), gold (Au), copper (Cu), aluminum (Al), and alloys thereof.

The passivation layer may include at least one layer selected from aluminum oxide (Al2O3), aluminum nitride (AlN), aluminum oxynitride (AlON), a silicon oxide (SiOx), a silicon nitride (SixNy), a silicon oxynitride (SixOyNz), silicon carbide (SiC), a titanium oxide (TiOx), and intrinsic amorphous silicon (a-Si-i).

The passivation layer may be formed with a metal oxide having a negative fixed charge.

The passivation layer may be made of two layers including a first passivation layer and a second passivation layer, the first passivation layer contacting the back surface of the first semiconductive substrate may be formed of a metal oxide having a negative fixed charge, and the second passivation layer contacting the lower portion of the first passivation layer may be formed of a silicon nitride (SixNy) or a silicon oxide (SiOx).

The first passivation layer may be thinner than the second passivation layer.

The passivation layer may include two or more layers.

The second electrode may be formed of silver (Ag), gold (Au), copper (Cu), aluminum (Al), or alloys thereof.

A first semiconductive type of back surface electric field layer (BSF) is formed in the second surface of the first semiconductive substrate contacting the second electrode through the opening.

At least one intrinsic silicon thin film formed between the first surface of the first semiconductive substrate and the second semiconductive layer may be further included.

A first semiconductive diffusion layer formed in the second surface of the first semiconductive substrate may be further included.

An impurity concentration of the back surface electric field layer may be higher than an impurity concentration of the first semiconductive diffusion layer.

The second surface of the first semiconductive substrate may further include a second semiconductive diffusion layer formed through diffusion of a second semiconductive type of impurity.

The first semiconductive substrate may include an n-type or p-type impurity.

A solar cell according to a second exemplary embodiment includes: a first semiconductive substrate; at least one intrinsic silicon thin film formed on a front surface of the first semiconductive substrate; a second semiconductive silicon thin film formed on the intrinsic silicon thin film; a transparent conductive layer formed on the second semiconductive silicon thin film; a front surface electrode formed on the transparent conductive layer; at least one passivation layer formed in the back surface of the first semiconductive substrate; at least one opening formed in the passivation layer; a back surface electrode contacting the back surface of the first semiconductive substrate through the opening; and a first semiconductive type of back surface electric field layer region contacting the back surface electrode through the opening and formed in the back surface of the first semiconductive substrate.

At least one thin film selected from amorphous silicon carbide (a-SiC), an amorphous silicon oxide (a-SiO), and an amorphous silicon nitride (a-SiN) formed between the intrinsic silicon thin film and the second semiconductive amorphous silicon thin film may be further included.

The passivation layer may include a first passivation layer and a second passivation layer, the first passivation layer contacting the back surface of the first semiconductive substrate may be formed of a metal oxide having a negative fixed charge, and the second passivation layer contacting the lower portion of the first passivation layer may be formed of a silicon nitride (SixNy) or a silicon oxide (SiOx).

A solar cell according to a third exemplary embodiment includes: a first semiconductive substrate; at least one intrinsic amorphous silicon thin film formed on a front surface of the first semiconductive substrate; a second semiconductive silicon thin film formed on the amorphous silicon thin film; a transparent conductive layer formed on the second conductive silicon thin film; a front surface electrode formed on the transparent conductive layer; a first semiconductive diffusion layer formed in the back surface of the first semiconductive substrate; at least one passivation layer formed in the back surface of the first semiconductive diffusion layer; at least one opening formed in the passivation layer; a back surface electrode contacting the back surface of the first semiconductive substrate through the opening; and a first semiconductive type of back surface electric field layer contacting the back surface electrode through the opening and formed in the back surface of the first semiconductive substrate, wherein the impurity concentration of the back surface electric field layer is higher than the impurity concentration of the first semiconductive diffusion layer.

At least one thin film selected from amorphous silicon carbide (a-SiC), an amorphous silicon oxide (a-SiO), and an amorphous silicon nitride (a-SiN) between the amorphous silicon thin film and the second semiconductive amorphous silicon thin film may be further included.

A solar cell according to an exemplary further embodiment includes: a first semiconductive substrate; at least one intrinsic amorphous silicon thin film formed on a front surface of the first semiconductive substrate; a second semiconductive silicon thin film formed on the amorphous silicon thin film; a transparent conductive layer formed on the second semiconductive silicon thin film; a front surface electrode formed on the transparent conductive layer; a second semiconductive diffusion layer formed in the back surface of the first semiconductive substrate and diffused by the second semiconductive type of impurity; at least one passivation layer formed in the back surface of the second semiconductive diffusion layer; at least one opening formed in the passivation layer; a back surface electrode contacting the back surface of the first semiconductive substrate through the opening; and a first semiconductive type of back surface electric field layer contacting the back surface electrode through the opening and formed in the back surface of the first semiconductive substrate.

At least one thin film selected from amorphous silicon carbide (a-SiC), amorphous silicon oxide (a-SiO), and amorphous silicon nitride (a-SiN) formed between the amorphous silicon thin film and the second semiconductive amorphous silicon thin film may be further included.

The passivation layer may include a first passivation layer and a second passivation layer, the first passivation layer contacting the back surface of the first semiconductive substrate may be formed of a metal oxide having a negative fixed charge, and the second passivation layer contacting the lower portion of the first passivation layer may be formed of silicon nitride (SiNx) or silicon oxide (SiOx).

A solar cell according to yet another exemplary embodiment includes: a second semiconductive substrate; at least one intrinsic amorphous silicon thin film formed on a front surface of the second semiconductive substrate; a first semiconductive silicon thin film formed on the amorphous silicon thin film; a transparent conductive layer formed on the first semiconductive silicon thin film; a front surface electrode formed on the transparent conductive layer; at least one passivation layer formed in the back surface of the second semiconductive substrate; at least one opening formed in the passivation layer; a back surface electrode contacting the back surface of the second semiconductive substrate through the opening; and a second semiconductive type of back surface electric field layer contacting the back surface electrode through the opening, and formed in the back surface of the second semiconductive substrate.

A second semiconductive diffusion layer formed between the back surface of the second semiconductive substrate and the passivation layer may be further included.

An impurity concentration of the second semiconductive type back surface electric field layer may be higher than an impurity concentration of the second semiconductive diffusion layer.

A manufacturing method of a solar cell according to an exemplary embodiment includes: depositing at least one passivation layer in a back surface of a first semiconductive substrate; forming an opening in the passivation layer; forming a back surface electrode in the back surface and the opening of the passivation layer; diffusing the back surface electrode layer to form a back surface electric field layer; sequentially forming an amorphous silicon thin film and a second semiconductive silicon thin film in the front surface of the first semiconductive substrate; forming a transparent conductive layer on the second semiconductive silicon thin film; and forming a front surface electrode on the transparent conductive layer.

The method may further include diffusing a first semiconductive material in the back surface of the first semiconductive substrate before depositing the passivation layer to form a first semiconductive diffusion layer.

An impurity concentration of the back surface electric field layer may be higher than an impurity concentration of the first semiconductive diffusion layer.

The method may further include diffusing a second semiconductive material in the back surface of the first semiconductive substrate before depositing the passivation layer to form a second semiconductive diffusion layer.

The sequential deposition of the silicon thin film and the second semiconductive silicon thin film may form a bandgap layer between the silicon thin film and the second semiconductive silicon thin film.

As described above, a solar cell according to the present disclosure has a hetero-junction structure (e.g., P/N or P/I/N) at a front surface portion thereof such that free electron hole pairs may be generated and an output voltage may be obtained, and the process of directly doping impurities of the n-type or the p-type to the semiconductor substrate when forming the p-n hetero-junction structure in the semiconductor substrate is eliminated such that damage to the silicon surface may be avoided. Also, charge loss due to electron-hole recombination is reduced through the passivation layer formed in the semiconductor substrate back surface such that the leakage current may be reduced. Also, the passivation layer formed in the back surface functions as a reflection layer such that the inner light absorption may be improved.

Accordingly, according to the present disclosure of invention, the front surface of the semiconductor substrate has the hetero-junction structure and the back surface of the semiconductor substrate has the passivation layer such that the efficiency of the solar cell may be improved.

### BRIEF DESCRIPTION OF THE DRAWINGS

FIG. 1 is a cross-sectional view of a solar cell according to a first exemplary embodiment.

FIG. 2A to FIG. 2G are cross-sectional views sequentially showing a manufacturing method of the solar cell shown in FIG. 1.

FIG. 3 is a cross-sectional view of a solar cell according to a second exemplary embodiment.

FIG. 4A to FIG. 4H are cross-sectional views sequentially showing a manufacturing method of the solar cell shown in FIG. 3.

FIG. 5 is a cross-sectional view of a solar cell according to a third exemplary embodiment.

FIG. 6 is a cross-sectional view of a solar cell according to a fourth exemplary embodiment.

FIG. 7 is a cross-sectional view of a solar cell according to a fifth exemplary embodiment.

FIG. 8 is a cross-sectional view of a solar cell according to a seventh exemplary embodiment.

FIG. 9 is a cross-sectional view of a solar cell according to an eighth exemplary embodiment.

FIG. 10 is a cross-sectional view of a solar cell according to a ninth exemplary embodiment.

FIG. 11 is a cross-sectional view of a solar cell according to yet another exemplary embodiment.

### DETAILED DESCRIPTION

The present disclosure of invention will be provided more fully hereinafter with reference to the accompanying drawings, in which exemplary embodiments in accordance with the disclosure are shown. As those skilled in the art will realize from review of this disclosure, the described embodiments may be modified in various different ways, all without departing from the spirit or scope of the present teachings.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be understood that when an element such as a layer, film, region, or substrate is referred to as being “under” another element, it can be directly under the other element or intervening elements may also be present.

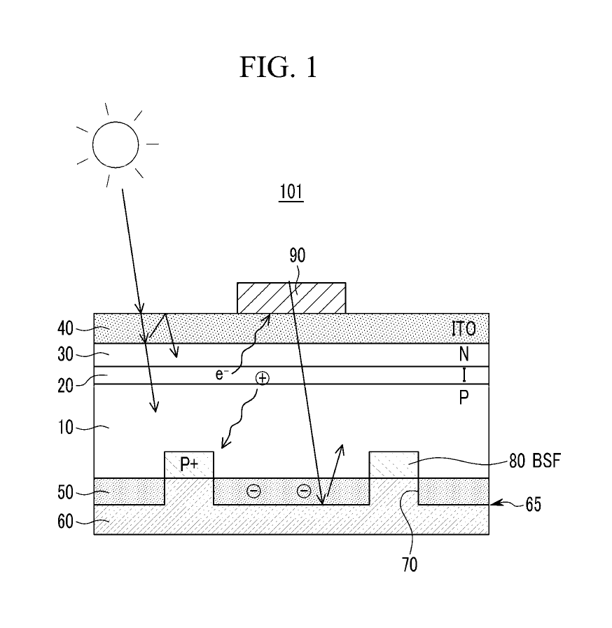

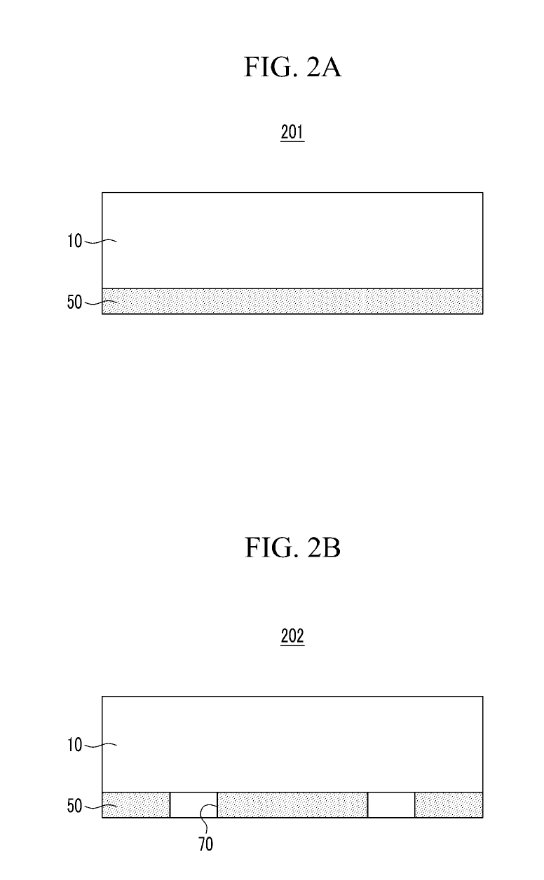

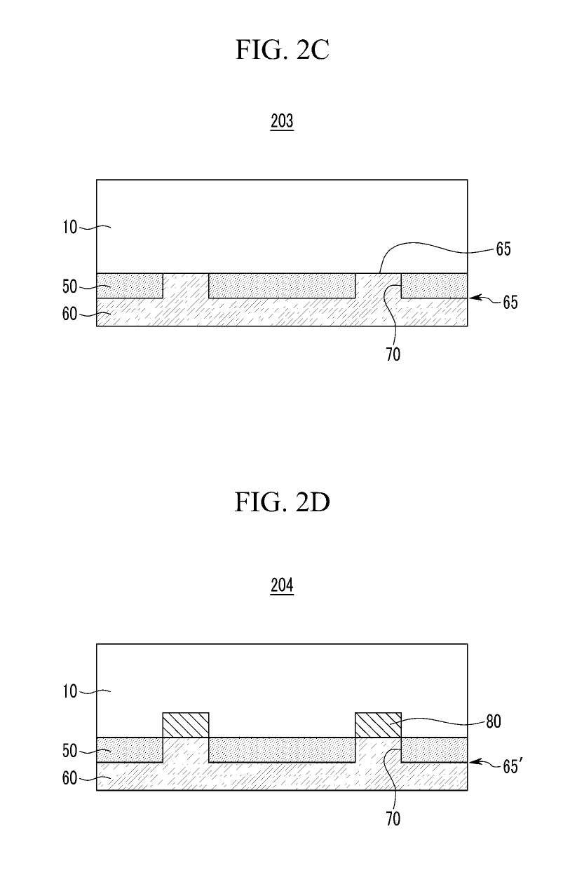

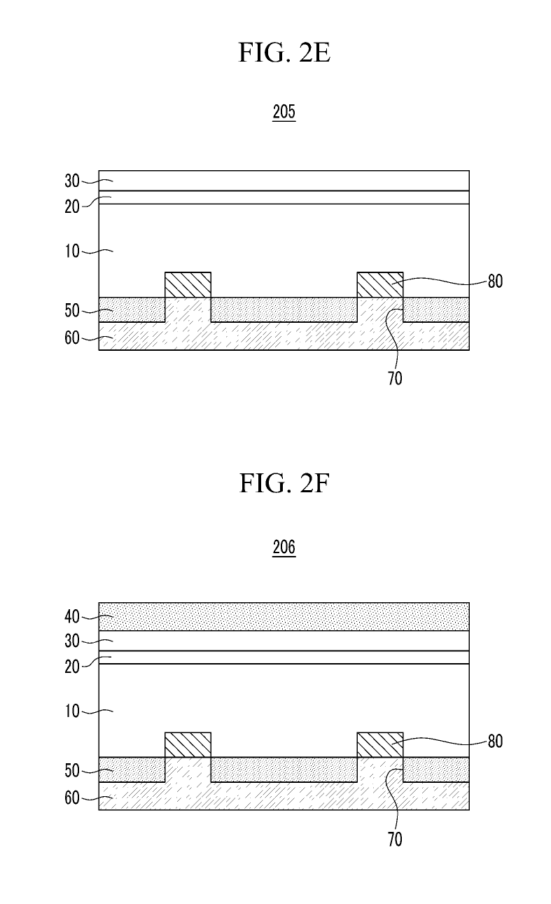

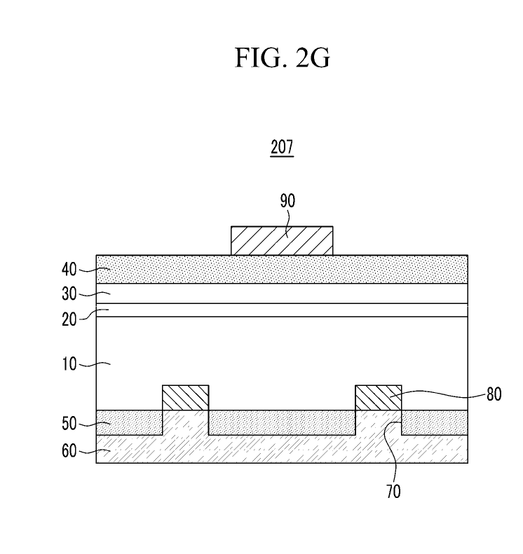

Now, a solar cell and a manufacturing method thereof according to an exemplary first embodiment will be described with reference to FIG. 1 and FIG. 2A to FIG. 2G.

FIG. 1 is a cross-sectional view of a solar cell according to the first exemplary embodiment of the present invention.

Referring to FIG. 1, a solar cell 101 according to the first exemplary embodiment is shown. Solar radiation is understood to impinge upon the cell 101 by way of its illustrated top side (upon which element 90 is located). The illustrated PV solar cell 101 includes an amorphous silicon (Si-a) layer 20, a second semiconductive silicon thin film 30 (also referred to as a second semiconductive layer, e.g., N-type Si), a transparent conductive layer 40, and one or more front surface electrodes 90 (also referred to as first electrodes) that are formed on the front surface of the transparent conductive layer 40. The PV solar cell 101 further includes a first semiconductive substrate 10 (e.g., P-type Si) disposed under the amorphous silicon (Si-a) layer 20, a passivation layer 50 formed under a back surface of the first semiconductive substrate 10, where one or more openings 70 are defined through the passivation layer 50 to allow for electrical connection to the back surface of the first semiconductive substrate 10. The PV solar cell 101 further includes one or more back surface electric field (BSF) layer portions 80 formed at regions communicating with the openings 70. The BSF layer portions 80 connect to the back surface of the first semiconductive substrate 10 and they are doped (heavily doped) with a conductivity type defining impurity (P+or N+) of relatively high concentration. The PV solar cell 101 further includes one or more back surface electrodes 60 (referred to as second electrodes) formed on the back surface of the cell 101.

The first semiconductive substrate 10 may be formed of single crystal silicon (monocrystalline silicon or Si-m) or of polycrystalline silicon (Si-p). In one embodiment, the body of the first semiconductive substrate 10 is provided as a monolithic Si-m or Si-p wafer wherefrom one or more replicas of the illustrated PV solar cell 101 may be integrally formed. Typically, the so-provided wafer form of the first semiconductive substrate 10 is pre-diffused with p-type or n-type impurity atoms of relatively light concentrations (less than P+or N+). Alternatively, the dominant conductivity type (N or P) of the initially provided, first semiconductive substrate 10 may be established with appropriate doping.

The p-type impurity atoms may be impurity atoms included in group III of the Periodic Table, and the n-type impurity atoms may be impurity atoms included in group V such as phosphorus (P).

The top and bottom surfaces of the initially provided first semiconductive substrate 10 may be treated by respective surface texturing and cleaning processes. For example the top surface of the first semiconductive substrate 10 may be treated by surface texturing so that it then has at least one of protrusions or depressions or honeycomb shaped regions, for example of polygon pyramid shapes. The first semiconductive substrate 10 treated by the surface texturing has a larger surface area than a conventional planar wafer such that the absorption/reflection ratio may be increased and thus undesired reflectance of incoming solar radiation may be reduced, thereby improving the efficiency of the solar cell.

The amorphous silicon thin film layer 20 (e.g., intrinsic layer) is formed (e.g., deposited) on the front surface of the first semiconductive substrate 10, and the second semiconductive silicon thin film 30 is then formed thereon as an amorphous film. The transparent conductive layer 40 is formed on the second semiconductive amorphous silicon thin film 30.

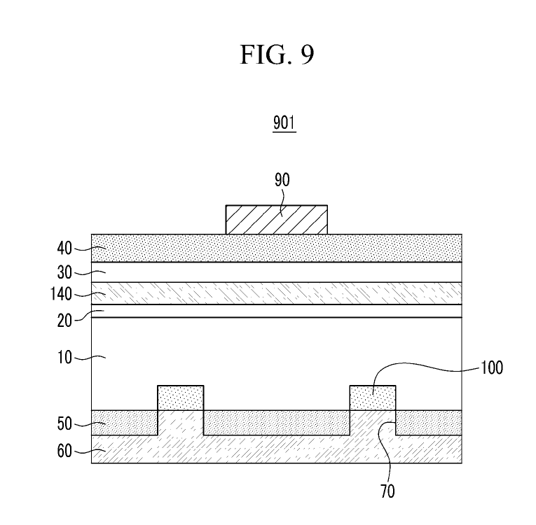

A plurality of layers increasing in respective optical bandgaps may be deposited between the amorphous silicon thin film 20 and the second semiconductive amorphous silicon thin film 30. This will be described in the exemplary embodiment of FIG. 9 to FIG. 11.

The transparent conductive layer 40 may include at least one of transparent conductive materials such as ITO, a-ITO, IZO, ZnO, and SnOx. The transparent conductive layer 40 spreads out over the surface area of the second semiconductive silicon thin film 30 and thereby functions to reduce an effective contact resistance as between the second semiconductive silicon thin film 30 and the one or more front surface electrodes 90 provided on the second semiconductive silicon thin film 30. The front surface electrode 90 formed on the transparent conductive layer 40 gathers the charge carriers (e⁻ or holes) present in the second semiconductive amorphous silicon thin film 30 and transmits the so-gathered charge carriers (e⁻ or positive current flow) to an external device. The front surface electrodes 90 may be made of one or more layers of metal having low resistivity such as silver (Ag), gold (Au), copper (Cu), aluminum (Al), and alloys thereof.

The electrically insulative passivation layer 50 is formed under the back surface of the first semiconductive substrate 10. The passivation layer 50 may made of a metal oxide such as aluminum oxide (Al2O3), aluminum nitride (AlN), aluminum oxynitride (AlON), a silicon oxide (SiOx), silicon nitride (SixNy), a silicon oxynitride (SixOyNz), silicon carbide (SiC), a titanium oxide (TiOx), and/or an intrinsic amorphous silicon (a-Si-i) where x, y, z are understood here to be compositional variables. More specifically, in the case of SiOx, x may be 2 whereby stoichiometric glass (SiO2) is then represented. For the case of (SixNy), x may be 3 while y is 4 whereby stoichiometric Si3N4 is then represented.

The passivation layer 50 may have a thickness of about 5 nm to 3000 nm, but is not limited thereto. For example, when the passivation layer 50 having a negative fixed charge such as aluminum oxide (Al2O3; or a metal oxide) is used as a dielectric layer in the back surface of the substrate, a thickness of about 5 nm may obtain a sufficient effect thereof. On the other hand, when the passivation layer is made of the material such as a silicon nitride (SixNy) or a silicon oxide (SiOx), the thickness thereof may be increased to achieve desired electrical insulation.

Also, it is preferable that the thickness is more than 800 nm to absorb the long wavelength of 1100 nm in the back surface of the semiconductor substrate for the function of the reflective layer.

In an alternate embodiment, it may be preferable for the passivation layer 50 formed on the back surface of the first semiconductive substrate 10 to be a passivation layer having a negative fixed charge.

In detail, when the passivation layer 50 has a plurality of negative charges embedded or trapped therein and the first semiconductive substrate 10 is of P-type conductivity, the negatively charged passivation layer 50 helps to prevent electrons (e⁻) as minority charges from existing in the first semiconductive substrate 10 close to the repulsively charged passivation layer 50 and it thus helps to prevent electrons (e⁻) from moving to the side of the back surface of the first semiconductive substrate 10 (i.e., the side of the back surface electrode 60). Accordingly, both of free electrons and free holes are prevented from being present near the back side of the first semiconductive substrate 10 and therefore desired holes (free+charges) may be prevented from recombining with and thus being extinguished by free electrons (e⁻) lurking near the back surface of the first semiconductive substrate 10. Accordingly, free charge loss due to recombination is decreased such that the efficiency of the solar cell may be increased.

The back surface electrode 60 is formed under the passivation layer 50. The back surface electrode 60 may be made of reflective and/or opaque semiconductive metals such as silver, aluminum (Al), copper and/ or plural layers thereof and each layer may have a thickness of about 2 to 50 μm or more.

The back surface electrode 60 makes ohmic contact with the back surface of the first semiconductive substrate 10 by way of the one or more openings 70 formed through corresponding contact enabling portions of the passivation layer 50.

The back surface electric field layer portions (back surface field, BSF) 80 are positioned in the locations where the back surface of the first semiconductive substrate 10 is electrically exposed for ohmic contact by the back surface electrode 60. The back surface electric field layer (back surface field, BSF) portions 80 may act similar to heavily doped (e.g., P+) regions so as to prevent opposed charges from forming therein and being recombined and extinguished near the back surface of the first semiconductive substrate 10. Accordingly, conversion efficiency of the solar cell 101 may be increased.

Also, since the second electrode 60 is made of one or more reflective metals (e.g., a multilayer structure having silver as one of its reflective layers) such that the light passing through the first semiconductive substrate 10 is again reflected toward the inside the first semiconductive substrate 10 when it strikes the combination of the passivation layer 50 and second electrode 60, nonconversion of light (light leakage) is reduced and the efficiency is thereby increased.

A manufacturing method for a solar cell such as 101 of FIG. 1 will now be described according to an exemplary embodiment and with reference to FIG. 2A to FIG. 2G.

FIG. 2A to FIG. 2G are cross-sectional views sequentially showing a manufacturing method of the solar cell 101 shown in FIG. 1.

Firstly, the first semiconductive substrate 10 is provided in an initial form such as that of a monolithic silicon wafer (monocrystalline or polycrystalline in its bulk). Here, the first semiconductive substrate 10 may be pre-doped with a p-type impurity in the bulk of its body and it may optionally have P+heavy doping in a thin layer at its bottom.

Also, although not shown in the drawings, the first semiconductive substrate 10 may be treated through surface texturing to have a nonplanar top surface and the layers that are conformably formed on top of the textured top surface may then also take on nonplanar layer shapes such as for example those coating a honeycombed matrix of polygon-based pyramids (e.g., hexagon based).

In one embodiment, the front (top) surface layers of the solar cell 101 are formed with low temperature processes to thus define the hetero junction structure (e.g., P/N or P/I/N) of the device while the initial base substrate 10 is formed with high temperature annealing and purifying (gettering) and doping processes. More specifically, the back surface of initial wafer 10 may be subjected to a process of diffusing dopants through the back surface of the semiconductor substrate 10 towards it front such that a doping gradient is established with greater than dopant concentrations near the back (bottom side of 10) and thus the back is subjected to higher processing temperatures than the front surface. In one embodiment, formation of the second semiconductive silicon thin film 30 near the front part of cell 101 entails depositing amorphous silicon (e.g., by CVD) at a temperature of about 200° C. to 300° C. On the other hand, the doping process applied to the back portion of the cell 101 (for the bulk impurity diffusion) may entail using higher energy temperatures of about 500° C. to 1000° C. Accordingly, the back surface portion (10) of the cell 101 is formed first at the higher temperatures and thereafter the front layer structures are added for example by use of low temperature chemical vapor deposition (CVD), sputtering or other appropriate means.

Referring to FIG. 2A, after the initial first semiconductive substrate 10 has been pre-processed by texturing and so forth, the material of the passivation layer 50 is formed on the back surface of the first semiconductive substrate 10. Here, the passivation layer 50 may be formed of one or more insulative and transparent or reflective layers of materials that are selected for example from the group consisting of aluminum oxide (Al2O3), aluminum nitride (AN), aluminum oxynitride (AlON), a silicon oxide (SiOx), a silicon nitride (SixNy), a silicon oxynitride (SixOyNz), silicon carbide (SiC), a titanium oxide (TiOx), and intrinsic amorphous silicon (a-Si-i).

Referring to FIG. 2B, one or more openings 70 are formed in the passivation layer 50.

Here, the forming of the openings 70 may be performed using various methods such as irradiating laser and wet-etching or dry-etching using an etch mask.

Referring to FIGS. 2B and 2C, a back surface electrode 60 is next fitted across the whole back surface (specifically, under the passivation layer 50 and in alignment with the openings 70) of the in-process structure 203. Here, the attachment of the back surface electrode 60 may be performed using a method comprising: first coating a conductive adhesion, binder material or paste 65 on the top of the back surface electrode 60 (where 60 is disc shaped in its bulk) by a spin coating or a sputtering process. Also, the conductive adhesion layer/paste 65 for the back surface electrode 60 may be pre-filled into the openings 70, and also the conductive adhesion or binder layer/paste 65 for the back surface electrode 60 may be coated so as to cover the whole back surface of the first semiconductive substrate 10. Here, the method of filling the semiconductive adhesion layer/paste 65 for the back surface electrode 60 may include various methods such as screen printing, inkjet printing, and coining printing.

The semiconductive adhesion layer/paste material 65 for the back surface electrode 60 may include a metal powder which can form a P-type silicide when thermally combined with silicon such as aluminum powder.

Referring to the next in-process structure 204 of FIG. 2D, with the semiconductive adhesion layer/paste material 65 coated on the back surface (specifically, inside openings 70 of the passivation layer 50) and the back surface electrode 60 press fitted to mate with the openings 70, the in-process structure 203 of FIG. 2C is left in a furnace at a high temperature for firing. The firing may be executed at a temperature higher than a curing or melting temperature of the adhesion layer/paste material 65 (e.g., of the aluminum metal powder), for example at about 500 to 1000° C. so that the adhesion layer/paste material 65 is thereby activated to provide adhesion between the back surface electrode 60 and layers 50 and 10. The thickness of the back surface electrode 60 may be in the range of 2 to 50 μm.

When the back surface electrode 60 is thus adherently attached by the firing process, a back surface electric field layer (back surface field, BSF) 80 is simultaneously formed by diffusion of diffusible particles of the adhesion layer/paste material 65 (e.g., of the aluminum) through openings 70 and into the opening exposed portions of the back surface of the first semiconductive substrate 10. For example, when the material forming the back surface electrode 60 is aluminum (Al), aluminum particles are diffused by the high temperature process to combine with the adjacent silicon material such that a silicide back surface electric field layer portion (back surface field, BSF) 80 of p-type conductivity is formed.

The firing process for curing the adhesion layer/paste material 65 and thereby simultaneously forming the back surface electric field layer (back surface field) 80 is not explicitly shown in the drawings, however it may be implemented by firing in an oven, by irradiating with a laser, by exothermic reaction and so forth after the back surface electrode 60 and adhesion layer/paste material 65 are applied to the pre-patterned passivation layer 50. In one embodiment, the openings 70 of the passivation layer 50 may be simultaneously formed with deposition of the material of layer 50.

Also, after forming the openings 70 of the passivation layer 50, the adhesion layer/paste material 65 which may include P+doping impurities is activated by the oven firing or the irradiating with a spot heating laser at the high temperature for the formation of the back surface electric field layer portions 80.

Referring to FIG. 2E, an amorphous and intrinsic silicon thin film 20 (a-Si-i) and doped material (e.g., N-type) for forming the second semiconductive silicon thin film 30 are sequentially deposited on the front surface of the first semiconductive substrate 10 where both deposition may be performed in a same process chamber.

The amorphous and intrinsic silicon thin film 20 may be formed through plasma enhanced chemical vapor deposition (PECVD) to a thickness in a range of about 20 Å to 100 Å, and dopant free silicon providing compounds such as silane (SiH4) may be flowed through the vacuum or low pressure chamber for the formation thereof.

The second semiconductive silicon thin film 30 is formed on the amorphous silicon thin film 20. The second semiconductive amorphous silicon thin film 30 includes dopants of the opposite impurity type to the first semiconductive substrate 10, and thus the p-i-n hetero junction of the PV solar cell 101 is formed.

The second semiconductive silicon thin film 30 may be formed through PECVD, and a silicon and hydrogen compound such as SiH4 may be inserted along with the doping impurity. Here, the impurity may be the n-type impurity when the bulk layer 10 is doped to have p-type conductivity. The thickness may be in the range of about 20 Å to 100 Å. Alternatively, if the bulk layer 10 is doped to have n-type conductivity, the upper semiconductive layer 30 will be doped with a p-type impurity.

After deposition, one or both of the amorphous silicon thin film 20 and the second semiconductive amorphous silicon thin film 30 may be left in amorphous form (as a-Si) or one or both of them may be re-crystallized with a laser process or another appropriate means to thus form a micro-crystallized or polycrystallized silicon layer.

The amorphous silicon thin film 20 and the second semiconductive amorphous silicon thin film 30 may be formed through one method among thin film deposition methods including chemical vapor deposition (CVD) or physical vapor deposition (PVD). Also, they may be formed through one method selected from the group including sputtering, E-beam evaporation, thermal evaporation, laser molecular beam epitaxy (L-MBE), pulsed laser deposition (PLD), metal-organic chemical vapor deposition (MOCVD), hybrid vapor phase epitaxy (HVPE), CVD, and atomic layer deposition (ALD), however it is not limited thereto, and may be formed by other appropriate methods as will be understood by person of ordinary skill in the semiconductor fabrication art.

Next, referring to FIG. 2F (in-process structure 206), a method of forming a transparent conductive layer 40 on the second semiconductive silicon thin film 30 will be described.

The transparent conductive layer 40 is formed on the second semiconductive amorphous silicon thin film 30 by CVD or sputtering. The thickness of the transparent conductive layer 40 may be in the range of 10 to about 1000 Å. The transparent conductive layer 40 may be made of a material such as ITO, a-ITO, IZO, ZnO, SnOx, or another appropriate material that is substantially transparent to the to be absorbed solar radiation and is also electrically conductive as described above.

Next, as shown in FIG. 2G (in-process structure 207), the front surface electrode(s) 90 is/are formed in spaced apart fashion on the transparent conductive layer 40 so as to provide a relatively large aperture ratio of allowing incoming solar radiation to pass through to the layers below.

In one embodiment, the front surface electrodes 90 are made of a conductive paste through Inkjet printing, screen printing, offset printing, or gravure printing.

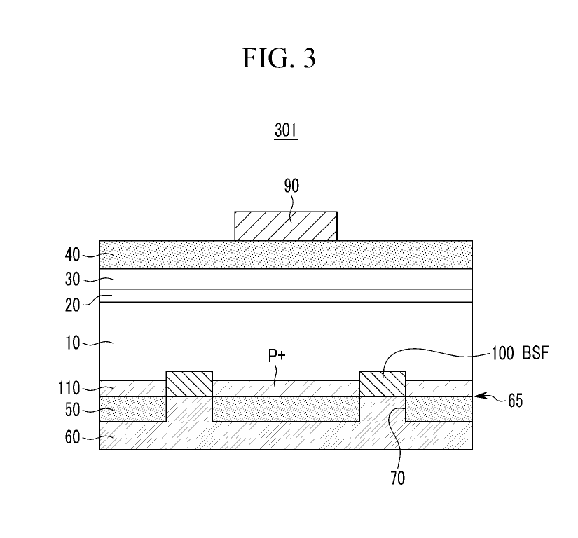

FIG. 3 is a cross-sectional view of a solar cell according to the second exemplary embodiment 301 in accordance with the present disclosure of invention.

Referring to FIG. 3, a solar cell 301 according to the second exemplary embodiment includes the amorphous intrinsic silicon (a-Si-i) layer 20, the second semiconductive silicon thin film 30, the transparent conductive layer 40, and the front surface electrode 90 formed in the front surface of the first semiconductive substrate 10, the passivation layer 50 formed in the back surface of the first semiconductive substrate 10, a first semiconductive diffusion layer 110 which is over-doped and is interposed between the passivation layer 50 and the first semiconductive substrate 10, with at least one opening 70 being formed in the passivation layer 50, a back surface electric field layer 100 formed in the region where the opening 70 and a back surface of the additional electric field layer 110 contact and that is inserted with the impurity with the high concentration, and the back surface electrode 60 formed in the back surface.

That is, the solar cell 301 according to the second exemplary embodiment mostly has the same structure as its front surface as does the first exemplary embodiment 101, but the second solar cell 301 differs from the first exemplary embodiment in that the illustrated semiconductive diffusion layer 110 is wholly formed in the back surface of the first semiconductive substrate 10 of the second exemplary embodiment. Also, the second exemplary embodiment 301 differs from the back surface electric field layer 80 of the first exemplary embodiment 101 in that the illustrated back surface electric field layer 100 extends through the semiconductive diffusion layer 110 as shown. This can cause the two layers to substantially have different characteristics due the difference of the circumference structure during the manufacturing process.

The first semiconductive substrate 10 may originate as a single crystal or poly-crystalline silicon wafer. Also, the first semiconductive substrate 10 may be originally diffused in bulk with p-type or n-type impurity atoms.

The p-type impurity atoms may be impurity atoms included in group III, and the n-type impurity atoms may be impurity atoms included in group V such as phosphorus (P).

The surface of the first semiconductive substrate 10 may be treated by surface texturing. The first semiconductive substrate 10 treated by the surface texturing may then have surface protrusions or depressions and/or a honeycombed structure, for example one composed of hexagon-based pyramid shapes. The first semiconductive substrate 10 so treated by the surface texturing process then has a wide surface area such that the absorption ratio may be increased and the reflectance may be reduced, thereby improving the efficiency of the solar cell 301.

The amorphous intrinsic silicon thin film 20 is formed in the front surface of the first semiconductive substrate 10, and the second semiconductive amorphous silicon thin film 30 is formed thereon. The transparent conductive layer 40 is formed on the second semiconductive amorphous silicon thin film 30.

A plurality of layers increasing in respective optical bandgaps may be deposited between the amorphous silicon thin film 20 and the second semiconductive amorphous silicon thin film 30. This will be described in an exemplary embodiment of FIG. 9 to FIG. 11.

The transparent conductive layer 40 may include at least one of transparent conductive materials such as ITO, a-ITO, IZO, ZnO, and SnOx. The transparent conductive layer 40 functions for reducing the contact resistance along with the front surface electrode 90 of the first semiconductive substrate 10. The front surface electrode 90 formed on the transparent conductive layer 40 gathers the charge carriers generated through the first semiconductive substrate 10 and the second semiconductive amorphous silicon thin film 30 and transmits them to an external device, and may made of a metal having low resistivity such as silver (Ag), gold (Au), copper (Cu), aluminum (Al), and alloys thereof.

The passivation layer 50 is formed in the back surface of the first semiconductive substrate 10. The passivation layer 50 may made of materials such as aluminum oxide (Al2O3), aluminum nitride (AN), aluminum oxynitride (AlON), silicon oxide (SiOx), silicon nitride (SiNx), silicon oxynitride (SiOxNy), silicon carbide (SiC), titanium oxide (TiOx), and amorphous silicon (a-Si). The passivation layer 50 may have a thickness of about 5 nm to 3000 nm, but is not limited thereto.

In detail, when the passivation layer 50 has a plurality of negative charges embedded therein, the passivation layer 50 may prevent by way of mutual repulsion, free electrons present as minority charges from co-existing in the back of the first semiconductive substrate 10 and from moving to the back surface of the first semiconductive substrate 10 (i.e., the side near the back surface electrode 60), such that the free minority electrons with recombine and free holes thereat and thus extinguish the free holes near the back surface of the first semiconductive substrate 10. Accordingly, the charge loss is decreased such that the efficiency of the solar cell 301 may be increased.

The first semiconductive diffusion layer 110 is formed between the passivation layer 50 and the first semiconductive substrate 10. The first semiconductive diffusion layer 110 is formed in the back surface of the first semiconductive substrate 10 by way of over-doping. According to the exemplary embodiment, it may be formed by p+high-doping by use of diffusion of high concentrations of boron (B).

The back surface electrode 60 is formed under the passivation layer 50. The back surface electrode 60 may be made of an opaque metal such as aluminum (Al), and may have a thickness of about 2 to 50 μm.

The back surface electrode 60 contacts the back surface of the first semiconductive substrate 10 through at least at least one of openings 70 formed in the portion of the passivation layer 50.

The back surface electric field layer 100 is positioned in the portion where the back surface of the first semiconductive substrate 10 and the back surface electrode 60 contact each other. The back surface electric field layer 100 and the first semiconductive diffusion layer 110 prevent the charges from being recombined and extinguished near the back surface of the first semiconductive substrate 10 such that the efficiency of the solar cell may be increased.

Also, the second electrode 60 is made of a reflective opaque metal such that the light passing through the first semiconductive substrate 10 is again reflected inside the first semiconductive substrate 10, and thereby the light leakage is prevented and efficiency is increased.

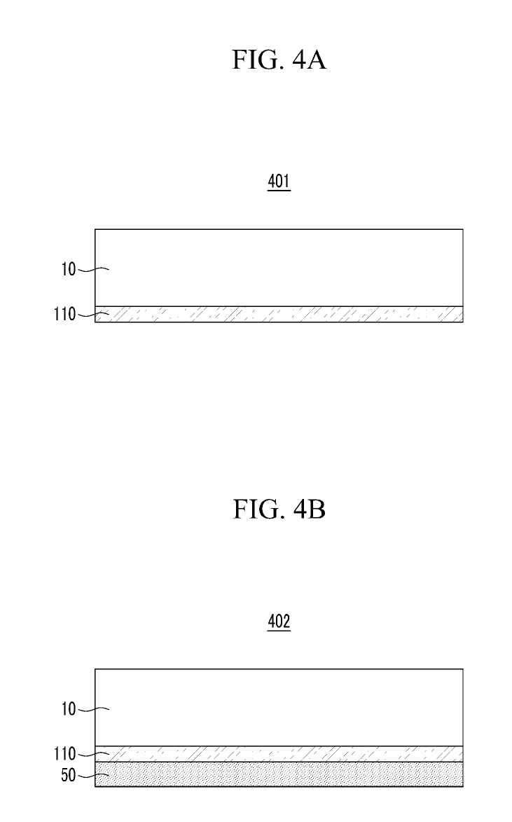

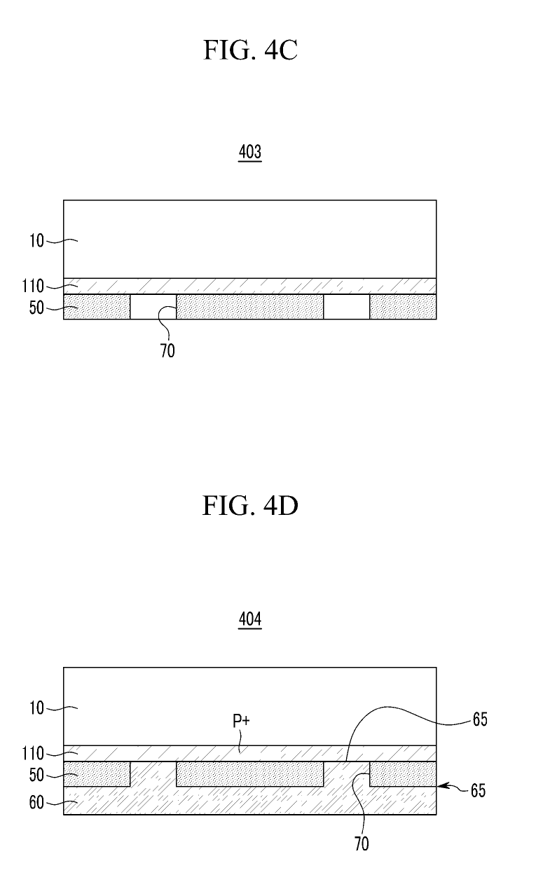

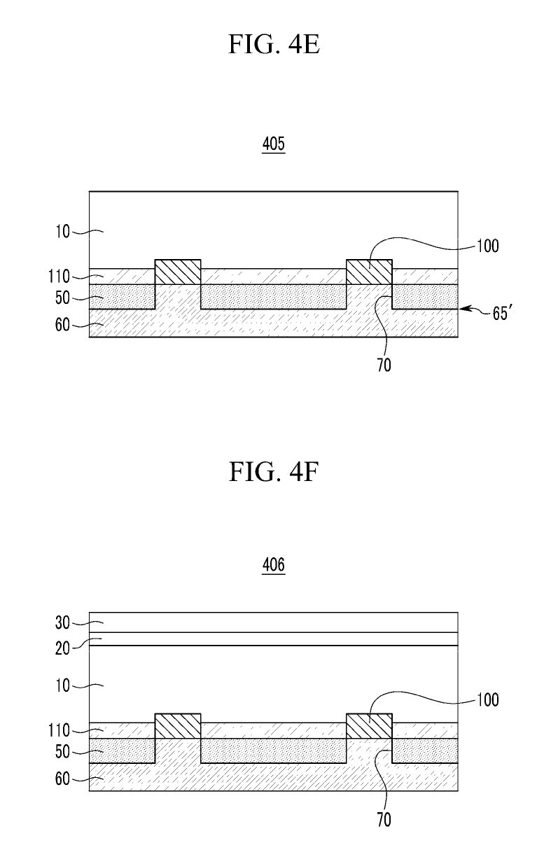

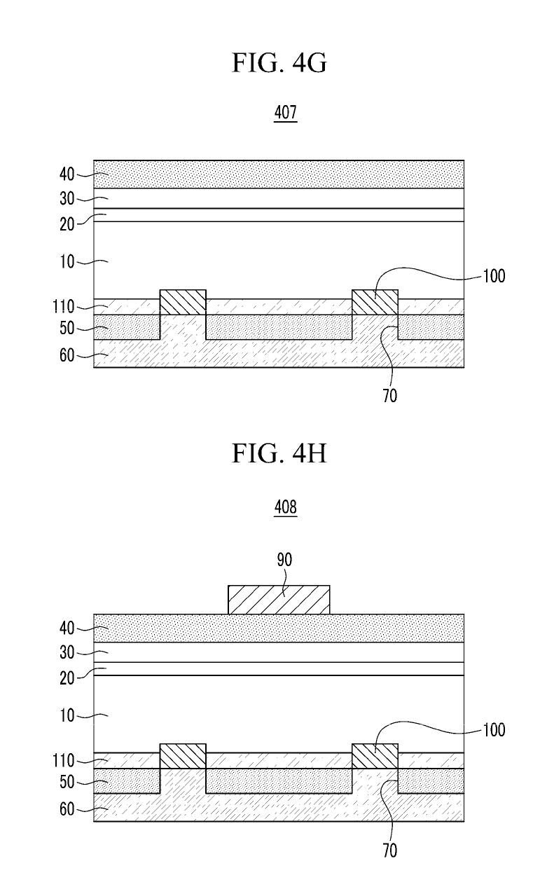

A manufacturing method of a solar cell 301 according to the second exemplary embodiment will now be described with reference to FIG. 4A to FIG. 4G as well as FIG. 2.

FIG. 4A to FIG. 4G are cross-sectional views sequentially showing a manufacturing method of the solar cell 301 shown in FIG. 3.

Referring to FIG. 4A, the first semiconductive type of first semiconductive diffusion layer 110 is formed on the whole surface of the back surface of the first semiconductive substrate 10. Here, the first semiconductive type of first semiconductive diffusion layer 110 may be formed as a p-type by the diffusion of high concentrations of a p-type impurity such as boron (B).

Next, referring to FIG. 4B, the passivation layer 50 is formed under the back surface of the first semiconductive substrate 10 formed with the first semiconductive diffusion layer 110.

Next, as shown in FIG. 4C, at least one opening 70 is formed in the passivation layer 50 by for example using a laser. The method of forming the opening 70 may be the same as that of the first exemplary embodiment.

Next, as shown in FIG. 4D, the back surface electrode layer 60 is bound to the in-process embodiment 404 so as to be disposed under the passivation layer 50 including the opening 70. Here, while the back surface electrode layer 60 is fired and formed with a binding material (65) provided between electrode layer 60 and the embodiment 403 of FIG. 4C, the back surface electric field layer 100 is formed on the portion contacting the first semiconductive diffusion layer 110 where the back the surface electrode layer 60 and the first semiconductive type semiconductor substrate 10 are doped and formed through the opening. For example, particles from the back surface electrode layer 60 when made of aluminum (Al) is passed through the first semiconductive diffusion layer 110 and is diffused into the first semiconductive substrate 10, thereby forming the back surface electric field layer 100 in the opening (referring to FIG. 4E).

The method of forming the back surface electric field layer 100 on the portion where the back surface electrode layer 60 and the back surface of the first semiconductive type semiconductor substrate 10 (specifically, the first semiconductive diffusion layer 110) contact through the opening may be the same as in the first exemplary embodiment.

Here, the impurity concentration of the back surface electric field layer 100 may be higher than the first semiconductive diffusion layer 110 wholly formed in the back surface of the first semiconductive type semiconductor substrate 10.

For example, the impurity concentration of the first semiconductive diffusion layer 110 formed in the back surface of the first semiconductive substrate 10 may be in the atoms-per range of 10¹⁹/cm³-10²⁰/cm³, and the impurity concentration of the back surface electric field formed in the portion where the back surface electrode layer 60 and the back surface of the first semiconductive type semiconductor substrate 10 contact through the opening is in the range of 10²⁰/cm³-10²¹/cm³ which is higher by 10 times (e.g., at least one order of magnitude greater).

FIG. 4F to FIG. 4H sequentially show the method of forming the front surface of the first semiconductive substrate 10. This is the same as the first exemplary embodiment such that additional description is omitted.

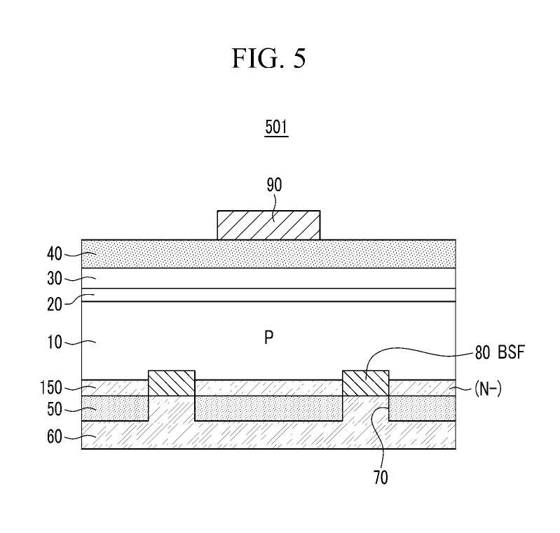

FIG. 5 is a cross-sectional view of a solar cell 501 according to another exemplary embodiment.

Referring to FIG. 5, the solar cell 501 according to the third exemplary embodiment includes a second semiconductive diffusion layer 150 formed in the back surface of the first semiconductive substrate 10, differently from the first and second exemplary embodiments. Compared with the second exemplary embodiment, in the third exemplary embodiment, the second semiconductive diffusion layer 150 is formed differently from, and in place of the first semiconductive diffusion layer 110. While the first semiconductive diffusion layer 110 of the second exemplary embodiment (301) is over-doped with the first semiconductive material (e.g., P+), contrastingly however the second semiconductive diffusion layer 150 of the third exemplary embodiment 501 is lightly-doped with opposed second semiconductive material (e.g., N−) so that a charge carrier entrapping PN junction is formed at the interface of layers 10 and 150.

In the third exemplary embodiment, the second semiconductive diffusion layer 150 formed in the back surface of the first semiconductive substrate 10 decreases the back surface recombination speed of electrons and increases the hole-to-electron converting capacity of the solar cell 501.

Also, the structure of the front surface of the solar cell according to the third exemplary embodiment is the same as the first and second exemplary embodiments.

A manufacturing method of the solar cell according to the third exemplary embodiment of the present invention will be described.

The second semiconductive diffusion layer 150 is formed in the back surface of the first semiconductive substrate 10. Here, the second semiconductive diffusion layer 150 may be formed as the n-type by the impurity diffusion of phosphorus (P). Also, the second semiconductive diffusion layer 150 preferable has a low concentration (N−).

On the other hand, when forming the second semiconductive diffusion layer 150, the other layer may not be formed in the front surface of the first semiconductive substrate 10.

Next, the passivation layer 50 is formed in the back surface of the first semiconductive substrate.

In the third exemplary embodiment 501, the method of forming the passivation layer 50, the method of forming the opening 70, the method of forming the front surface electrode layer 90, the method of forming the back surface electrode layer 60, and the method of forming the back surface electric field layer (BSF) 80 in the opening 70 are substantially the same as in the first exemplary embodiment.

Here, the semiconductive type of the back surface electric field layer (BSF) 80 formed in the opening 70 is different from the semiconductive type of the second semiconductive diffusion layer 150.

Also, as shown in later discussed FIG. 9 to FIG. 11, at least one layer made of the material having the wide optical bandgap may be deposited between the amorphous silicon thin film 20 and the second semiconductive amorphous silicon thin film 30.

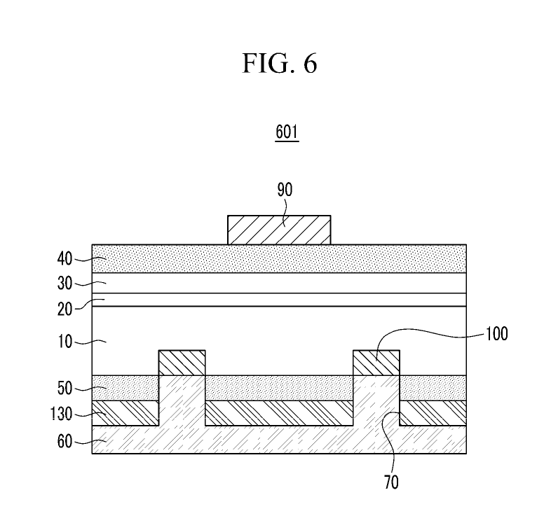

FIG. 6 is a cross-sectional view of a solar cell 601 according to another exemplary embodiment.

As shown in FIG. 6, the solar cell 601 according to the fourth exemplary embodiment includes passivation layers 50 and 130 such that at least two layers are deposited.

In FIG. 6, the passivation layer 50 as one layer is deposited in the structure of FIG. 1, and the passivation layer may be made of at least one selected from the group of aluminum oxide (Al2O3), aluminum nitride (AN), aluminum oxynitride (AlON), silicon oxide (SiOx), silicon nitride (SiNx), silicon oxynitride (SiOxNy), silicon carbide (SiC), titanium oxide (TiOx), and amorphous silicon (a-Si).

The passivation layer 130 that is additionally deposited helps to again reflect light passing through the first semiconductive substrate 10 back toward the first semiconductive substrate 10 thereby being reabsorbed such that the loss of the light is prevented and the efficiency may be increased. In addition, the passivation layer 50 and the first semiconductive substrate 10 may be prevented from being damaged by the high temperature firing when forming the back surface electrode 60.

Also, the passivation layer 50 formed in the back surface of the first semiconductive substrate 10 is formed with the low deposition speed such that the thickness of the passivation layer 50 formed in the back surface of first semiconductive substrate 10 may be decreased and the thickness of the passivation layer 130 formed thereunder may be increased through the long process time. For example, aluminum oxide (Al2O3) having the negative fixed charge is formed with the high quality by using atomic layer deposition (ALD), and the deposition speed may be about 0.25 Å per second. This is the slower speed than that of CVD by about 3 to 5 times. Although the passivation layer formed in the back surface of the semiconductor substrate and preventing the electrons from being moved toward the back surface has the thickness of 5 nm, the function thereof may be executed, and the passivation layer is formed with the thickness of 50 nm for the aspect of the stability of the layer quality. The passivation layer 130 formed under aluminum oxide (Al2O3) executes the function of the passivation layer and the function of the reflection layer such that it is formed with a thickness of about 800 nm to 3200 nm.

When the passivation layers 50 and 130 are deposited in the back surface of the first semiconductive substrate 10, the passivation layer 50 directly formed in the back surface of the first semiconductive substrate 10 may use the passivation layer including the metal oxide material having the negative fixed charges such as aluminum oxide (Al2O3), and accordingly when the passivation layer 50 acquires the plurality of negative charges, and the so negatively-charged passivation layer 50 inhibits electrons which are minority charges from existing near the back surface in the first semiconductive substrate 10 and from being moved toward the back surface such that the electrons and the holes being recombined and extinguished in the side of the back surface of the first semiconductive substrate 10 may be prevented. Accordingly, the loss of the charges is decreased such that the efficiency of the solar cell may be increased.

Also, the passivation layer 130 may be formed by depositing a silicon oxide (SiOx) or a silicon nitride (SiNx) under aluminum oxide (Al2O3).

As described above, the passivation layer 130 formed under aluminum oxide (Al2O3) has the functions of a reflection layer and a passivation layer.

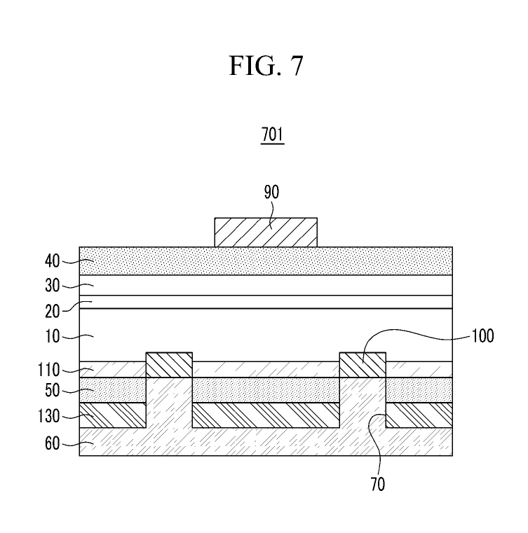

FIG. 7 is a cross-sectional view of a solar cell 701 according to another exemplary embodiment.

In FIG. 7, two or more passivation layers 50 and 130 are deposited.

FIG. 7 shows the structure in which the passivation layers 50 and 130 of two layers are deposited in the structure of FIG. 3.

The description of the passivation layers 50 and 130 is the same as that of the fourth exemplary embodiment.

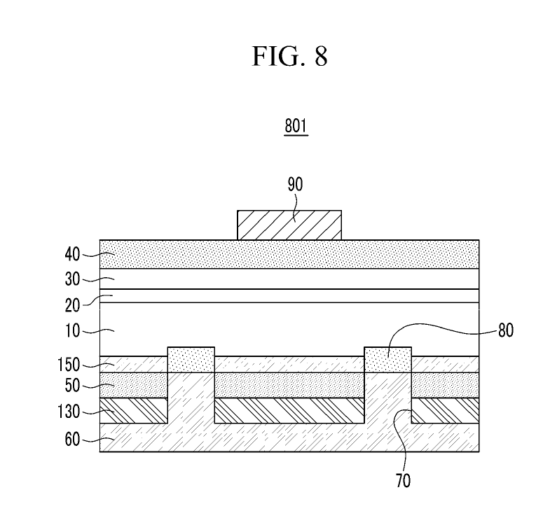

FIG. 8 is a cross-sectional view of a solar cell 801 according to another exemplary embodiment.

In FIG. 8, the passivation layers 50 and 130 are deposited with two or more layers.

FIG. 8 shows the structure in which the passivation layers 50 and 130 are deposited with two layers in the structure of FIG. 5.

The description of the passivation layers 50 and 130 is the same as that of the fourth exemplary embodiment.

FIG. 9 is a cross-sectional view of a solar cell 901 according to another exemplary embodiment.

FIG. 9 shows a plurality of layers 140 (hereinafter referred to as bandgap layers) that successively increase in respective optical bandgap and are deposited between the amorphous silicon thin film 20 and the second semiconductive amorphous silicon thin film 30 in the structure of FIG. 1. In FIG. 9, the bandgap layer 140 is shown as one layer, however it may have the plurality of layers as described above.

The bandgap layer 140 may be formed with at least one made of amorphous silicon carbide (a-SiC), amorphous silicon oxide (a-SiO), or amorphous silicon nitride (a-SiN). The bandgap layer 140 may have the characteristics of the amorphous intrinsic silicon thin film 20.

In this way, by forming the bandgap layer 140, the light absorption is increased and the current loss is decreased such that the efficiency of the solar cell may be increased.

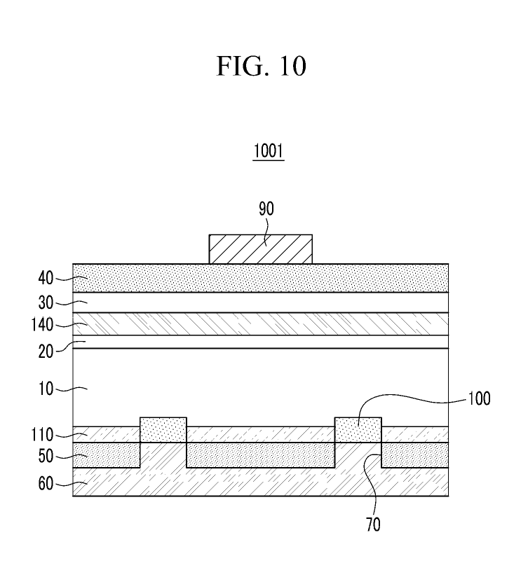

FIG. 10 is a cross-sectional view of a solar cell 1001 according to another exemplary embodiment.

FIG. 10 shows the bandgap layer 140 deposited between the amorphous silicon thin film 20 and the second semiconductive amorphous silicon thin film 30 in the structure of FIG. 3. Layer 110 is included.

The bandgap layer 140 is the same as the seventh exemplary embodiment.

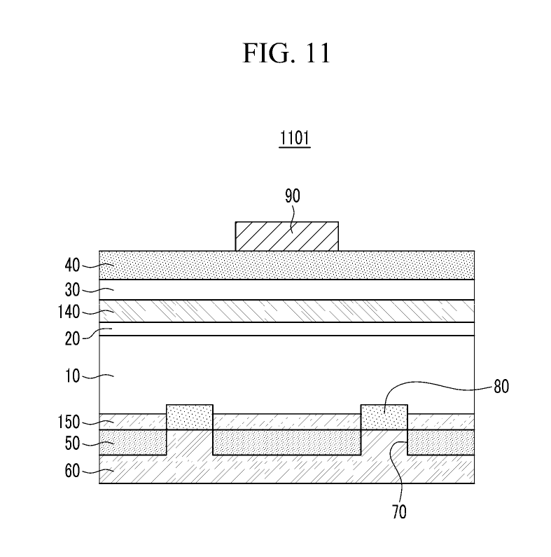

FIG. 11 is a cross-sectional view of a solar cell 1101 according to a ninth exemplary embodiment.

FIG. 11 shows the bandgap layer 140 deposited between the amorphous silicon thin film 20 and the second semiconductive amorphous silicon thin film 30 in the structure of FIG. 5. Layer 150 is included.

The bandgap layer 140 is the same as the seventh exemplary embodiment.

The present disclosure of invention is provided by way of the here detailed first exemplary embodiment to ninth exemplary embodiment. However the present teachings are not limited thereto and several exemplary variations may be provided. For example, when using the second semiconductive substrate instead of the first semiconductive substrate 10, the first semiconductive amorphous silicon thin film may be formed in the front surface of the second semiconductive substrate, and the first semiconductive back surface electric field (BSF) may be formed in the back surface of the second semiconductive substrate.

While this disclosure of invention has been provided in connection with several exemplary embodiments, it is to be understood that the teachings are not limited to the disclosed embodiments, but, on the contrary, the teachings are intended to cover various modifications and equivalent arrangements that may be appreciated in light of the foregoing and are thus included within the spirit and scope of the present teachings.

What is claimed is:

1. A solar cell comprising:
a first semiconductive substrate of a first conductivity type;
a second semiconductive layer formed adjacent to a first surface of the first semiconductive substrate, the second semiconductive layer being of a second conductivity type opposite to the first conductivity type;
a first electrode formed on the second semiconductive layer;
at least one passivation layer formed on a second surface of the first semiconductive substrate, the at least one passivation layer having a corresponding at least one opening defined there through; and
a second electrode contacting the second surface of the first semiconductive substrate through the opening.

2. The solar cell of claim 1, further comprising
an intrinsic silicon thin film formed between the first surface of the first semiconductive substrate and the second semiconductive layer.

3. The solar cell of claim 2, further comprising
at least one thin film selected from amorphous silicon carbide (a-SiC), amorphous silicon oxide (a-SiO), and amorphous silicon nitride (a-SiN) disposed between the intrinsic silicon thin film and the second semiconductive layer.

4. The solar cell of claim 1, further comprising
a transparent conductive layer formed between the second semiconductive layer and the first electrode.

5. The solar cell of claim 4, wherein
the transparent conductive layer includes at least one transparent conductive material selected from ITO, a-ITO, IZO, ZnO, and SnOx.

6. The solar cell of claim 1, wherein
the first electrode is made of at least one of silver (Ag), gold (Au), copper (Cu), aluminum (Al), and alloys thereof.

7. The solar cell of claim 1, wherein
the passivation layer includes at least one layer selected from aluminum oxide (Al2O3), aluminum nitride (AN), aluminum oxynitride (AlON), a silicon oxide (SiOx), a silicon nitride (SiNx), a silicon oxynitride (SiOxNy), silicon carbide (SiC), a titanium oxide (TiOx), and intrinsic amorphous silicon (a-Si-i).

8. The solar cell of claim 7, wherein
the passivation layer is formed with a metal oxide having a negative fixed charge.

9. The solar cell of claim 7, wherein
the passivation layer is made of two layers including a first passivation layer and a second passivation layer, the first passivation layer contacting the back surface of the first semiconductive substrate is formed of a metal oxide having a negative fixed charge, and the second passivation layer contacting the lower portion of the first passivation layer is formed of a silicon nitride (SixNy) or a silicon oxide (SiOx).

10. The solar cell of claim 9, wherein
the first passivation layer is thinner than the second passivation layer.

11. The solar cell of claim 1, wherein
the passivation layer includes two or more layers.

12. The solar cell of claim 1, wherein
the second electrode is formed of at least one of silver (Ag), gold (Au), copper (Cu), aluminum (Al), or alloys thereof.

13. The solar cell of claim 1, further comprising
a first semiconductive type of back surface electric field layer formed in the second surface of the first semiconductive substrate contacting the second electrode through the opening.

14. The solar cell of claim 13, further comprising
at least one intrinsic silicon thin film formed between the first surface of the first semiconductive substrate and the second semiconductive layer.

15. The solar cell of claim 13, further comprising
a first semiconductive diffusion layer formed in the second surface of the first semiconductive substrate.

16. The solar cell of claim 15, wherein
an impurity concentration of the back surface electric field layer is higher than an impurity concentration of the first semiconductive diffusion layer.

17. The solar cell of claim 13, wherein
the second surface of the first semiconductive substrate further includes a second semiconductive diffusion layer formed through diffusion of a second semiconductive type of impurity.

18. The solar cell of claim 1, wherein
the first semiconductive substrate includes an n-type or p-type impurity.

19. A solar cell comprising:
a first semiconductive substrate of a first conductivity type;
at least one intrinsic amorphous silicon thin film formed on a front surface of the first semiconductive substrate;
a second semiconductive silicon thin film formed on the intrinsic amorphous silicon thin film, the second semiconductive silicon being of a second conductivity type opposite to the first conductivity type;
a transparent conductive layer formed on the second semiconductive silicon thin film;
a front surface electrode formed on the transparent conductive layer;
at least one passivation layer formed in the back surface of the first semiconductive substrate;
at least one opening formed in the passivation layer;
a back surface electrode contacting the back surface of the first semiconductive substrate through the opening; and
a first semiconductive type of back surface electric field layer contacting the back surface electrode through the opening and formed in the back surface of the first semiconductive substrate.

20. The solar cell of claim 19, further comprising
at least one thin film selected from amorphous silicon carbide (a-SiC), an amorphous silicon oxide (a-SiO), and an amorphous silicon nitride (a-SiN) formed between the intrinsic amorphous silicon thin film and the second semiconductive amorphous silicon thin film.

21. The solar cell of claim 20, wherein
the passivation layer includes a first passivation layer and a second passivation layer, the first passivation layer contacting the back surface of the first semiconductive substrate is formed of a metal oxide having a negative fixed charge, and the second passivation layer contacting the lower portion of the first passivation layer is formed of a silicon nitride (SixNy) or a silicon oxide (SiOx).

22. A solar cell comprising:
a first semiconductive substrate of a first conductivity type;
at least one intrinsic amorphous silicon thin film formed in a front surface of the first semiconductive substrate;
a second semiconductive silicon thin film formed on the intrinsic amorphous silicon thin film, the second semiconductive silicon thin film having a second conductivity type opposite of the first conductivity type;
a transparent conductive layer formed on the second semiconductive silicon thin film;
a front surface electrode formed on the transparent conductive layer;
a first semiconductive diffusion layer formed in the back surface of the first semiconductive substrate;
at least one passivation layer formed in the back surface of the first semiconductive diffusion layer;
at least one opening formed in the passivation layer;
a back surface electrode contacting the back surface of the first semiconductive substrate through the opening; and
a first semiconductive type of back surface electric field layer contacting the back surface electrode through the opening and formed in the back surface of the first semiconductive substrate,
wherein the impurity concentration of the back surface electric field layer is higher than the impurity concentration of the first semiconductive diffusion layer.

23. The solar cell of claim 22, further comprising
at least one thin film selected from amorphous silicon carbide (a-SiC), an amorphous silicon oxide (a-SiO), and an amorphous silicon nitride (a-SiN) disposed between the intrinsic amorphous silicon thin film and the second semiconductive amorphous silicon thin film.

24. A solar cell comprising
a first semiconductive substrate of a first conductivity type;
at least one intrinsic amorphous silicon thin film formed in a front surface of the first semiconductive substrate;
a second semiconductive silicon thin film formed on the amorphous silicon thin film, the second semiconductive silicon thin film being of a second conductivity type that is opposite to the first conductivity type;
a transparent conductive layer formed on the second semiconductive silicon thin film;
a front surface electrode formed on the transparent conductive layer;
a second semiconductive diffusion layer formed in the back surface of the first semiconductive substrate and diffused by the second semiconductive type of impurity;
at least one passivation layer formed in the back surface of the second semiconductive diffusion layer;
at least one opening formed in the passivation layer;
a back surface electrode contacting the back surface of the first semiconductive substrate through the opening; and
a first semiconductive type of back surface electric field layer contacting the back surface electrode through the opening and formed in the back surface of the first semiconductive substrate.

25. The solar cell of claim 24, further comprising
at least one thin film selected from amorphous silicon carbide (a-SiC), an amorphous silicon oxide (a-SiO), and an amorphous silicon nitride (a-SiN) formed between the intrinsic amorphous silicon thin film and the second semiconductive amorphous silicon thin film.

26. The solar cell of claim 25, wherein
the passivation layer includes a first passivation layer and a second passivation layer, the first passivation layer contacting the back surface of the first semiconductive substrate is formed of a metal oxide having a negative fixed charge, and the second passivation layer contacting the lower portion of the first passivation layer is formed of a silicon nitride (SixNy) or a silicon oxide (SiOx).

27. A solar cell comprising:
a second semiconductive substrate;
at least one amorphous silicon thin film formed in a front surface of the second semiconductive substrate;
a first semiconductive silicon thin film formed on the amorphous silicon thin film;
a transparent conductive layer formed on the first semiconductive silicon thin film;
a front surface electrode formed on the transparent conductive layer;
at least one passivation layer formed in the back surface of the second semiconductive substrate;
at least one opening formed in the passivation layer;
a back surface electrode contacting the back surface of the second semiconductive substrate through the opening; and
a second semiconductive type of back surface electric field layer contacting the back surface electrode through the opening, and formed in the back surface of the second semiconductive substrate.

28. The solar cell of claim 27, further comprising
a second semiconductive diffusion layer formed between the back surface of the second semiconductive substrate and the passivation layer.

29. The solar cell of claim 28, wherein
an impurity concentration of the second semiconductive type back surface electric field layer is higher than an impurity concentration of the second semiconductive diffusion layer.

30. A method for manufacturing a solar cell, comprising:
depositing at least one passivation layer in a back surface of a first semiconductive substrate, the first semiconductive substrate having a corresponding first conductivity type;
forming an opening through the passivation layer;
forming a back surface electrode in the back surface and the opening of the passivation layer;
diffusing the back surface electrode layer to form a back surface electric field layer;
sequentially forming an intrinsic amorphous silicon thin film and a second semiconductive silicon thin film on the front surface of the first semiconductive substrate, the second semiconductive silicon thin film having a second conductivity type that is opposite of the first conductivity type;
forming a transparent conductive layer on the second semiconductive silicon thin film; and
forming a front surface electrode on the transparent conductive layer.

31. The method of claim 30, further comprising
diffusing a first semiconductive material in the back surface of the first semiconductive substrate before depositing the passivation layer to form a first semiconductive diffusion layer.

32. The method of claim 31, wherein
an impurity concentration of the back surface electric field layer is higher than an impurity concentration of the first semiconductive diffusion layer.

33. The method of claim 32, wherein
the sequential deposition of the silicon thin film and the second semiconductive silicon thin film forms a bandgap layer between the silicon thin film and the second semiconductive silicon thin film.

34. The method of claim 30, further comprising
diffusing a second semiconductive material in the back surface of the first semiconductive substrate before depositing the passivation layer to form a second semiconductive diffusion layer.

35. The method of claim 34, wherein
the sequential deposition of the silicon thin film and the second semiconductive silicon thin film forms a bandgap layer between the silicon thin film and the second semiconductive silicon thin film.

36. The method of claim 30, wherein
the sequential deposition of the silicon thin film and the second semiconductive silicon thin film forms a bandgap layer between the silicon thin film and the second semiconductive silicon thin film.
